(19) United States
(12) Patent Application Publication
(10) Pub. No.: US 2021/0037646 A1
(43) Pub. Date: Feb. 4, 2021

(54) FLEXIBLE PRINTED CIRCUIT BOARD AND DISPLAY DEVICE

(71) Applicant: WUHAN CHINA STAR OPTOELECTRONICS TECHNOLOGY CO., LTD., Wuhan, Hubei (CN)

(72) Inventor: Jingjing XIAO, Wuhan, Hubei (CN)

(21) Appl. No.: 16/613,427

(22) PCT Filed: Sep. 16, 2019
(86) PCT No.: PCT/CN2019/106016

§ 371 Date: Nov. 14, 2019

(30) Foreign Application Priority Data
Jul. 30, 2019 (CN) 201910694836.9

(51) Int. Cl. H05K 1/11; H05K 1/18; G02F 1/1345

(52) U.S. Cl. CPC H05K 1/118; H05K 1/189; H05K 2201/09027; H05K 2201/056; H05K 2201/10136; G02F 1/13452

(57) ABSTRACT

A flexible printed circuit board includes a flexible substrate, through holes, a pin, and a metal trace. The through holes penetrate through the flexible substrate, and metal trace extends to both ends of the flexible substrate by the through holes and is electrically connected to the pin, so as to compress the bending space inside the flexible printed circuit board. Therefore, the display device has a screen with a high screen ratio.

### BACKGROUND OF INVENTION

### Field of Invention

The present invention relates to a flexible printed circuit board, and more particularly, to a flexible printed circuit board including through holes.

### Description of Prior Art

Referring to FIG. 1, a display device 100 includes a backlight module 101, a first substrate 102, a thin film transistor array substrate 103, a color filter 104, a second substrate 105, a control circuit board 106, and a flexible printed circuit board 107. The first substrate 102 is disposed on the backlight module 101. The flexible printed circuit board 107 is disposed on the thin film transistor array substrate 103. The thin film transistor array substrate 103 is disposed on the first substrate 101. The second substrate 105 is disposed on the color filter 104. The control circuit board 106 and the color filter 104 are disposed on the thin film transistor array substrate 103. The flexible printed circuit board 107 is disposed on the thin film transistor array substrate 103. There is a gap between the color filter 104 and the control circuit board 106. There is also a gap between the control circuit board 106 and the flexible printed circuit board 107. Specifically, the flexible printed circuit board 107 includes a flexible substrate 108, a pin 109, and a metal trace 110. A length of the pin 109 extends beyond the thin film transistor array substrate 103 by about 0.15 mm to 0.2 mm, so a gel 111 is required to protect the pin 109 from extending beyond the thin film transistor array substrate 103. In addition, it is also necessary to provide a protective layer 112 to protect an outer side of partial flexible substrate 108, and to provide the protective layer 112 having a length of 0.35 mm or more to protect an edge of the pin 109, thereby causing the flexible printed circuit board 107 to be unable to further bend inward.

In general, display devices include a flexible printed circuit board. The flexible printed circuit board includes a flexible substrate, a pin, and a metal trace. When the flexible printed circuit board is bonded to the thin film transistor array substrate in the display device, it is necessary to reserve a pin at the bonding place. The pin is electrically connected to the flexible printed circuit board through the metal trace, but a length of the pin extends beyond a length of the thin film transistor array substrate in the display device, thus requiring a gel to protect the pins extending beyond the length of the thin film transistor array substrate in the display device. In addition, a protective layer is required to protect the edge of the pin, thereby causing the flexible printed circuit board to be unable to further bend inward, and the display devices do not have screens with a high screen ratio.

### SUMMARY OF INVENTION

In a flexible printed circuit board according to one embodiment of the present invention, a metal trace extends to both ends of the flexible substrate by through holes and is electrically connected to the pin, so as to compress the bending space inside the flexible printed circuit board. Therefore, the display device has a screen with a high screen ratio, so as to solve the problems in the prior art.

A flexible printed circuit board includes a flexible substrate, through holes, a pin, and a metal trace. The through holes penetrate through the flexible substrate. The metal trace extends to both ends of the flexible substrate by the through holes and is electrically connected to the pin.

In one embodiment, the flexible printed circuit further includes a protective layer, and the protective layer covers the metal trace extending to the both ends of the flexible substrate by the through holes.

In one embodiment, the flexible printed circuit further includes an anisotropic conductive film.

In one embodiment, the anisotropic conductive film covers the pin.

In one embodiment, an inside of the through holes is coated with a metal layer.

In one embodiment, the through holes penetrating through the flexible substrate are arranged offset from each other.

In one embodiment, a hole diameter of the through holes is less than 0.1 mm.

A display device includes a backlight module, a first substrate, a thin film transistor array substrate, a color filter, a second substrate, a control circuit board, and a flexible printed circuit board. The first substrate is disposed on the backlight module. The thin film transistor array substrate is disposed on the first substrate. The second substrate is disposed on the color filter. The control circuit board and the color filter are disposed on the thin film transistor array substrate. The flexible printed circuit board is disposed on the thin film transistor array substrate. The flexible printed circuit board includes a flexible substrate, through holes, a pin, and a metal trace, and the through holes penetrate through the flexible substrate.

In one embodiment, the metal trace extends to both ends of the flexible substrate by the through holes and is electrically connected to the pin.

In one embodiment, the pin is electrically connected to the control circuit board through the metal trace.

A flexible printed circuit board includes a flexible substrate, through holes, a pin, a metal trace, and a protective layer. The through holes penetrate through the flexible substrate, and an inside of the through holes is coated with a metal layer. The metal trace extends to both ends of the flexible substrate by the through holes and is electrically connected to the pin. The protective layer covers the metal trace extending to the both ends of the flexible substrate by the through holes.

In one embodiment, the flexible printed circuit board further includes an anisotropic conductive film.

In one embodiment, the anisotropic conductive film covers the pin.

In one embodiment, the through holes penetrating through the flexible substrate are arranged offset from each other.

In one embodiment, a hole diameter of the through holes is less than 0.1 mm.

In a flexible printed circuit board of a display device according to an embodiment of the present invention, a metal trace extends to both ends of the flexible substrate by the through holes and is electrically connected to a pin, so as to compress the bending space inside the flexible printed circuit board. Therefore, the display device has a screen with a high screen ratio.

### BRIEF DESCRIPTION OF DRAWINGS

FIG. 1 is a schematic view of a display device.

FIG. 2 is a schematic view of a display device according to one embodiment of the present invention.

FIG. 3 is a schematic view of a flexible substrate according to an embodiment of the present invention.

FIG. 4 is a schematic view of a flexible substrate according to another embodiment of the present invention.

### DETAILED DESCRIPTION OF PREFERRED EMBODIMENTS

In a flexible printed circuit board of a display device according to an embodiment of the present invention, a metal trace extends to both ends of the flexible substrate by the through holes and is electrically connected to a pin, so as to compress the bending space inside the flexible printed circuit board. Therefore, the display device has a screen with a high screen ratio.

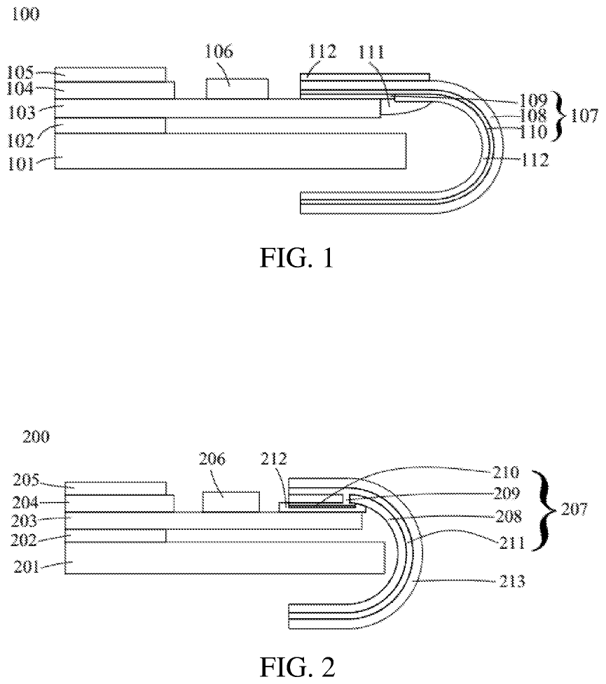

Referring to FIG. 2, a display device 200 includes a backlight module 201, a first substrate 202, a thin film transistor array substrate 203, a color filter 204, a second substrate 205, a control circuit board 206, and a flexible printed circuit board 207. Preferably, the display device 200 is a liquid crystal display device. Specifically, the first substrate 202 is disposed on the backlight module 201. The thin film transistor array substrate 203 is disposed on the first substrate 201. The second substrate 205 is disposed on the color filter 204. The control circuit board 206 and the color filter 204 are disposed on the thin film transistor array substrate 203. The flexible printed circuit board 207 is disposed on the thin film transistor array substrate 203. The first substrate 202 and the second substrate 205 are glass substrates. The flexible printed circuit board 207 includes a flexible substrate 208, through holes 209, a pin 210, and a metal trace 211. There is a gap between the color filter 204 and the control circuit board 206. There is also a gap between the control circuit board 206 and the flexible printed circuit board 207. In addition, the display device 200 further includes an anisotropic conductive film 212, and the anisotropic conductive film 212 covers a bottom and sides of the pin 210, and the pin 210 is disposed at the inner bottom of the flexible substrate 208. Therefore, it is no longer necessary to protect a side of the pin 210 with a gel, and it is not necessary to provide a protective layer on the inner side of the flexible substrate 208. Furthermore, the through holes 209 penetrate through the flexible substrate 208, and the through holes 209 penetrating through the flexible substrate 208 are arranged offset from each other. The metal trace 211 extends to both ends of the flexible substrate by the through holes and is electrically connected to the pin 210, and the pin 210 is electrically connected to the control circuit board 206 through the metal trace 211. An inside of the through holes 209 is coated with a metal layer. Preferably, the inner side of the through holes 209 is coated with a copper layer, and more preferably, a hole diameter of the through hole 209 is less than 0.1 mm. Moreover, the display device 200 further includes a protective layer 213. The protective layer 213 completely covers the metal trace 211 extending from the through holes 209 to both ends of the flexible substrate 208, and the protective layer 213 also completely covers an outer side of the flexible substrate 208. Comparing FIG. 2 with FIG. 1, the flexible printed circuit board of FIG. 2 can be further bent inward to compress the bending space inside the flexible printed circuit board.

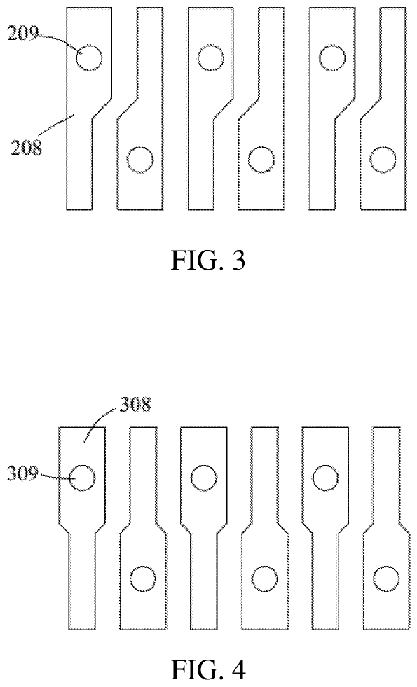

Referring to FIG. 3, since the through holes 209 are formed directly on the flexible substrate 208, a few through holes 209 overlap each other. Thus, an effective pressing cannot be formed, which affecting the pressing effect. Accordingly, the through holes 209 penetrating the flexible substrate 208 are disposed on the flexible substrate 208, and the through holes 209 are arranged offset from each other. In addition, a shape of the flexible substrate 208 may be a polygon, and the flexible substrates 208 are also arranged offset from each other.

Referring to FIG. 4, through holes 309 penetrating through the flexible substrate 308 are disposed on the flexible substrate 308. The through holes 309 are arranged offset from each other. The difference between FIG. 4 and FIG. 3 is that the shape of the flexible substrates is different.

The flexible printed circuit board according to one embodiment of the present invention does not need to additionally apply gel to protect the side of the pin, and it is not necessary to provide a protective layer on the inner side of the flexible substrate. Moreover, the metal trace extends to both ends of the flexible substrate by the through holes and is electrically connected to the pin, so as to compress the bending space inside the flexible printed circuit board. Therefore, the display device has a screen with a high screen ratio.

In the above, the present application has been described in the above preferred embodiments, but the preferred embodiments are not intended to limit the scope of the invention, and a person skilled in the art may make various modifications without departing from the spirit and scope of the application. The scope of the present application is determined by claims.

What is claimed is:

1. A flexible printed circuit board, comprising:
a flexible substrate;
through holes, wherein the through holes penetrate through the flexible substrate;
a pin; and
a metal trace, wherein the metal trace extends to both ends of the flexible substrate by the through holes and is electrically connected to the pin.

2. The flexible printed circuit board according to claim 1, further comprising a protective layer, wherein the protective layer covers the metal trace extending to the both ends of the flexible substrate by the through holes.

3. The flexible printed circuit board according to claim 1, further comprising an anisotropic conductive film.

4. The flexible printed circuit board according to claim 3, wherein the anisotropic conductive film covers the pin.

5. The flexible printed circuit board according to claim 1, wherein an inside of the through holes is coated with a metal layer.

6. The flexible printed circuit board according to claim 1, wherein the through holes penetrating through the flexible substrate are arranged offset from each other.

7. The flexible printed circuit board according to claim 1, wherein a hole diameter of the through holes is less than 0.1 mm.

8. A display device, comprising:
a backlight module;
a first substrate, wherein the first substrate is disposed on the backlight module;
a thin film transistor array substrate, wherein the thin film transistor array substrate is disposed on the first substrate;
a color filter;
a second substrate, wherein the second substrate is disposed on the color filter;
a control circuit board, wherein the control circuit board and the color filter are disposed on the thin film transistor array substrate; and
a flexible printed circuit board, wherein the flexible printed circuit board is disposed on the thin film transistor array substrate, the flexible printed circuit board comprises a flexible substrate, through holes, a pin, and a metal trace, and the through holes penetrate through the flexible substrate.

9. The display device according to claim 8, wherein the metal trace extends to both ends of the flexible substrate by the through holes and is electrically connected to the pin.

10. The display device according to claim 9, wherein the pin is electrically connected to the control circuit board through the metal trace.

11. A flexible printed circuit board, comprising:
a flexible substrate;
through holes, wherein the through holes penetrate through the flexible substrate, and an inside of the through holes is coated with a metal layer;
a pin;
a metal trace, wherein the metal trace extends to both ends of the flexible substrate by the through holes and is electrically connected to the pin; and
a protective layer, wherein the protective layer covers the metal trace extending to the both ends of the flexible substrate by the through holes.

12. The flexible printed circuit board according to claim 11, further comprising an anisotropic conductive film.

13. The flexible printed circuit board according to claim 12, wherein the anisotropic conductive film covers the pin.

14. The flexible printed circuit board according to claim 11, wherein the through holes penetrating through the flexible substrate are arranged offset from each other.

15. The flexible printed circuit board according to claim 11, wherein a hole diameter of the through holes is less than 0.1 mm.
